(19) United States
(12) Patent Application Publication
(10) Pub. No.: US 2008/0230782 A1
(43) Pub. Date: Sep. 25, 2008

(54) PHOTOCONDUCTIVE DEVICES WITH ENHANCED EFFICIENCY FROM GROUP IV NANOPARTICLE MATERIALS AND METHODS THEREOF

(76) Inventors: Homer Antoniadis, Mountain View, CA (US); Pingrong Yu, Sunnyvale, CA (US)

Correspondence Address: Foley & Lardner LLP, 150 East Gilman Street, Madison, WI, 53701-1497, US

(21) Appl. No.: 11/857,704

(22) Filed: Sep. 19, 2007

Related U.S. Application Data
(60) Provisional application No. 60/850,704, filed on Oct. 9, 2006.

(51) Int. Cl. H01L 31/0376; H01L 31/18

(52) U.S. Cl. 257/53; 438/96; 136/258; 257/E31.048

(57) ABSTRACT

A device for generating a plurality of electron-hole pairs from a photon is disclosed. The device includes a substrate, a first electrode formed above the substrate, and a first doped Group IV nanoparticle thin film deposited on the first electrode. The device further includes an intrinsic layer deposited on the first doped Group IV nanoparticle thin film, wherein the intrinsic layer includes a matrix material with a melting temperature T1, wherein T1 is greater than about 300° C., and a set of quantum confined nanoparticles each with a melting temperature T2, wherein T2 is less than about 900° C., wherein the melting temperature T1 is less than the melting temperature T2. The device also includes a second doped Group IV nanoparticle thin film deposited on the intrinsic layer, and a second electrode formed on the second doped Group IV nanoparticle thin film; wherein when the photon is absorbed by a quantum confined nanoparticle of the set of quantum confined nanoparticles, the plurality of electron-hole pairs is generated.

### CROSS-REFERENCE TO RELATED APPLICATIONS

This application claims the benefit of U.S. Provisional Patent Application Ser. No. 60/850,704 filed Oct. 9, 2006, the entire disclosure of which is incorporated by reference. The following commonly-assigned U.S. patent applications are co-pending with this application: (1) Semiconductor Devices and Methods from Group IV Nanoparticle Materials (filed Sep. 19, 2007); (2) Group IV Nanoparticles and Films Thereof (Ser. No. 11/842,466; filed Aug. 21, 2007); (3) Fullerene-Capped Group IV Semiconductor Nanoparticles and Devices Made Therefrom (Ser. No. 11/844,827; filed Aug. 24, 2007); and (4) Semiconductor Thin Films Formed from Group IV Nanoparticles (Ser. No. 11/851,004; filed Sep. 6, 2007). The entire disclosures of these applications are incorporated herein by reference.

### FIELD OF DISCLOSURE

This disclosure relates to photoconductive thin film devices fabricated using Group IV semiconductor nanoparticles, and methods for fabrication and use of such devices.

### BACKGROUND

The Group IV semiconductor materials enjoy wide acceptance as the materials of choice in a range devices in numerous markets such as communications, computation, and energy. Currently, particular interest is aimed in the art at improvements in devices utilizing semiconductor thin film technologies due to the widely recognized disadvantages of the current chemical vapor deposition (CVD) technologies. For example, some of the drawbacks of CVD technologies include, the high production of chemical wastes; the difficulty in accommodating large components, and high processing temperatures.

In that regard, with the emergence of nanotechnology, there is in general growing interest in leveraging the advantages of these new materials in order to produce low-cost devices with designed functionality using high volume manufacturing on nontraditional substrates. It is therefore desirable to leverage the knowledge of Group IV semiconductor materials and at the same time exploit the advantages of Group TV semiconductor nanoparticles for producing novel thin films, which may be readily integrated into a number of devices. Particularly, Group IV nanoparticles in the range of between about 1.0 nm to about 100.0 nm may exhibit a number of unique electronic, magnetic, catalytic, physical, optoelectronic, and optical properties due to quantum confinement and surface energy effects.

With respect to thin films compositions utilizing nanoparticles, U.S. Pat. No. 6,878,871 describes photovoltaic devices having thin layer structures that include inorganic nanostructures, optionally dispersed in a conductive polymer binder. Similarly, U.S. Patent Application Publication No. 2003/0226498 describes semiconductor nanocrystal/conjugated polymer thin films, and U.S. Patent Application Publication No. 2004/0126582 describes materials comprising semiconductor particles embedded in an inorganic or organic matrix. In U.S. Patent Application Publication No. 2006/0154036, composite sintered thin films of Group IV nanoparticles passivated, typically using an organic passivation layer, and hydrogenated amorphous Group IV materials are discussed. Notably, when these references disclose the use of Group IV nanoparticles for fabricating thin films, there are significant amounts of non-Group IV semiconductor materials present in the resulting thin films. As such, such thin films, and devices made from such thin films are substantially different than the well-accepted native Group IV semiconductor thin films

Regarding native Group IV semiconductor thin films, U.S. Pat. No. 5,576,248 describes Group IV semiconductor thin films formed from nanocrystalline silicon and germanium of 1.0 nm to 100.0 nm in diameter, where the film thickness is not more than three to four particles deep, and yielding film thickness of about 2.5 nm to about 20 nm. However, for many electronic and photoelectronic applications, Group IV semiconductor thin films of about 200 nm to 3 microns are desirable.

However, none of the above references address the issue of the use of Group IV semiconductor nanoparticles for enhancing the efficiency of photoconductive thin films.

Currently, there is emerging interest in harnessing the unique quantum confinement effects of nanoparticles in order to enhance the efficiency photoconductive thin film technology. For example, reports of multiple exciton generation (MEG) in quantum confined structures integrated into modifications of dye-sensitized photovoltaic cells have been given. In such devices, the dye molecules are substituted with quantum dots, which are adsorbed onto a nanocrystalline titanium dioxide thin film. Several types of quantum dots have been tried, such as indium phosphide, cadmium selenide, cadmium sulfide, and lead sulfide; all with some reported success. Still other approaches reported hybrid devices fabricated using cadmium selenide quantum dots forming junctions organic semiconductor polymers (see for example “Advanced Concepts for Photovoltaic Cells”; Nozik, A.; NREL/CP-590-33621; May 2003). While such approaches are helpful in advancing the art, they suffer from the use of highly toxic materials, and organic hybrid structures with as yet unproven durability versus vast historical knowledge of Group IV semiconductor materials.

As such, there is a need in the art for thin film photoconductive devices that have enhanced efficiency, and are additionally reliable, and reduce the use of toxic materials. Accordingly, devices made from native Group IV photoconductive thin films, which thin films additionally have Group IV semiconductor nanoparticles embedded within in order to enhance the efficiency of the thin film, address such a need.

### SUMMARY

The invention relates, in one embodiment, to a device for generating a plurality of electron-hole pairs from a photon. The device includes a substrate; an insulating layer formed above the substrate; and a first electrode formed above the insulating layer. The device also includes a first doped Group IV nanoparticle thin film deposited on the first electrode; and a second doped Group IV nanoparticle thin film deposited on the first doped Group IV nanoparticle thin film. The device further includes a second electrode formed on the second doped Group IV nanoparticle thin film, wherein when the photon is applied to the second doped Group IV nanoparticle thin film, the plurality of electron-hole pairs is produced.

The invention relates, in another embodiment, to a method of manufacturing a device for generating a plurality of electron-hole pairs from a photon. The method includes providing a substrate; forming an insulating layer above the substrate; and forming a first electrode above the insulating layer. The method also includes depositing a first doped Group IV nanoparticle thin film on the first electrode, depositing a second doped Group IV nanoparticle thin film on the first doped Group IV nanoparticle thin film, and forming a second electrode on the second doped Group IV nanoparticle thin film.

### BRIEF DESCRIPTION OF THE DRAWINGS

FIG. 1 is a diagram that depicts multiple exciton generation in a Group IV semiconductor nanoparticle.

FIG. 2 is a diagram that depicts the injection of charges into a bulk matrix from exciton generation in a Group IV semiconductor nanoparticle.

FIG. 3 is an embodiment of a single junction photoconductive thin film device with enhanced efficiency using Group IV semiconductor nanoparticles.

FIG. 4 is another embodiment of a single junction photoconductive thin film device with enhanced efficiency using Group IV semiconductor nanoparticles.

### DETAILED DESCRIPTION

Embodiments of devices formed from native Group IV semiconductor thin films, and methods for making such devices are disclosed herein. The thin films are formed from coating substrates using dispersions of Group IV nanoparticles, and fabricating the coated particle films to form photoconductive thin films with enhanced efficiency from which devices are made.

The embodiments of the disclosed photoconductive thin film devices fabricated from Group IV semiconductor nanoparticles starting materials evolved from the inventors' observations that by keeping embodiments of the native Group IV semiconductor nanoparticles in an inert environment from the moment they are formed through the formation of Group IV semiconductor thin films, that such thin films so produced have properties characteristic of native bulk semiconductor materials. In that regard, the photoconductive devices that are then fabricated from such thin films are formed from materials for which the electrical, spectral absorbance and photoconductive properties are well characterized. This is in contrast, for example, to the use of modified Group IV semiconductor nanoparticles, which modifications generally use organic species to stabilize the reactive particles, or mix the nanoparticles with organic modifiers, or both. In some such modifications, the Group IV nanoparticle materials are significantly oxidized. The use of these types of nanoparticle materials produces hybrid thin films, which hybrid thin films do not have as yet the same desirable properties as traditional Group IV semiconductor materials.

As used herein, the term “Group IV semiconductor nanoparticle” generally refers to hydrogen terminated Group IV semiconductor nanoparticles having an average diameter between about 1.0 nm to about 100.0 nm, and composed of silicon, germanium, and alpha-tin, and combinations thereof. As will be discussed subsequently, some embodiments of thin film devices utilize doped Group IV semiconductor nanoparticles. With respect to shape, embodiments of Group IV semiconductor nanoparticles include elongated particle shapes, such as nanowires, or irregular shapes, in addition to more regular shapes, such as spherical, hexagonal, and cubic nanoparticles, and mixtures thereof. Additionally, the nanoparticles may be single-crystalline, polycrystalline, or amorphous in nature. As such, a variety of types of Group IV semiconductor nanoparticle materials may be created by varying the attributes of elemental composition, size, shape, and crystallinity of Group IV semiconductor nanoparticles. Exemplary types of Group IV semiconductor nanoparticle materials are yielded by variations including, but not limited by: 1.) single or mixed elemental composition, including alloys, core/shell structures, doped nanoparticles, and combinations thereof; 2.) single or mixed shapes and sizes, and combinations thereof, and 3.) single form of crystallinity or a range or mixture of crystallinity, and combinations thereof.

In that regard, Group IV semiconductor nanoparticles have an intermediate size between individual atoms and macroscopic bulk solids. In some embodiments, Group IV semiconductor nanoparticles have a size on the order of the Bohr exciton radius (e.g. 4.9 nm), or the de Broglie wavelength, which allows individual Group IV semiconductor nanoparticles to trap individual or discrete numbers of charge carriers, either electrons or holes, or excitons, within the particle. The Group IV semiconductor nanoparticles may exhibit a number of unique electronic, magnetic, catalytic, physical, optoelectronic and optical properties due to quantum confinement and surface energy effects. For example, Group IV semiconductor nanoparticles exhibit luminescence effects that are significantly greater than, as well as melting temperatures of nanoparticles substantially lower than the complementary bulk Group IV materials. These unique effects vary with properties such as size and elemental composition of the nanoparticles. For example, and as will be discussed in more detail below, the melting of germanium nanoparticles is significantly lower than the melting of silicon nanoparticles of comparable size

Moreover, with respect to the quantum confinement effects, Group IV nanoparticle materials have discrete quantized levels than may enhance the conversion of high energy electrons to multiple electron/hole pairs, or excitons. Such an enhancement of multiple exciton generation (MEG) results in higher photoconduction in a device, and hence higher efficiency.

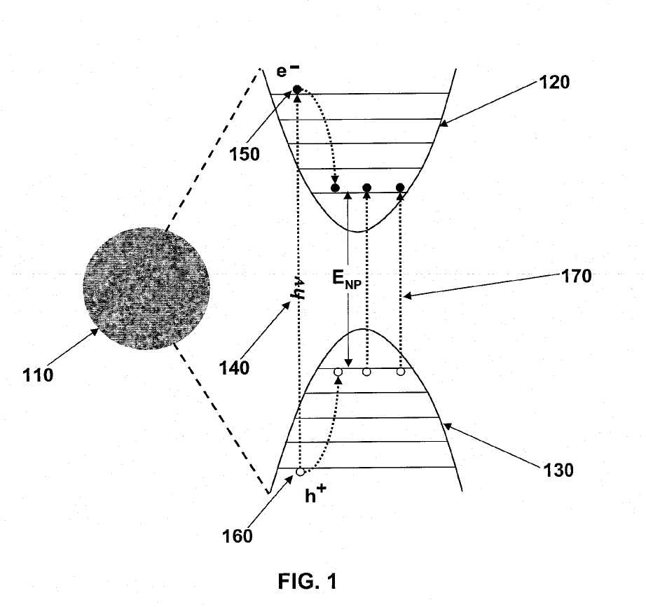

The phenomenon of MEG is illustrated in FIG. 1. Group IV semiconductor nanoparticle 110, has a conduction band comprised of quantized states 120, and a valence band comprised of quantized states 130. When a high-energy photon 140, defined as a photon having energy, h□ greater than the band gap of the nanoparticle, E_{NP}, is adsorbed by the Group IV semiconductor nanoparticle 110, it produces a high energy electron 150 and high energy hole 160 pair, or high energy exciton. Instead of dissipation of the high kinetic energy of the exciton formed as heat, the high energy exciton pair further generates more electron/hole pairs 170.

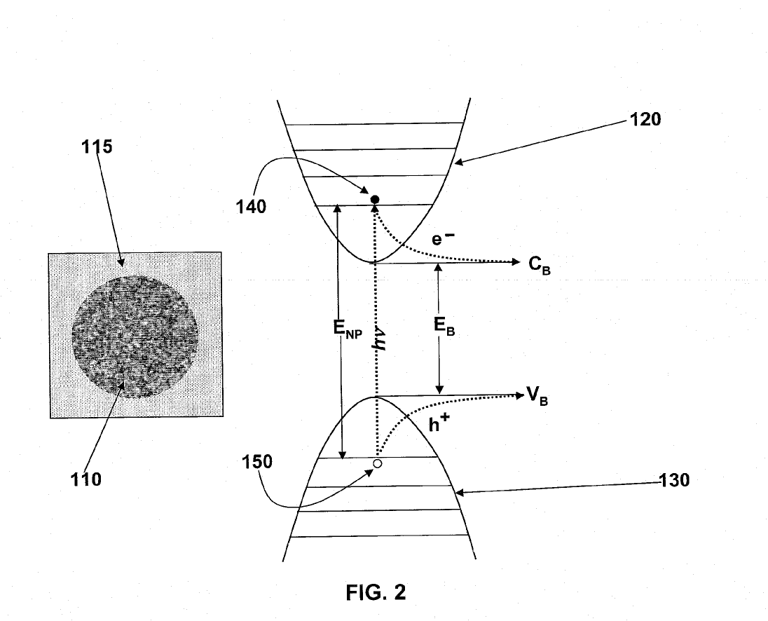

In FIG. 2, once an exciton, consisting of an electron 140 and hole 150 pair, has been created in a Group IV semiconductor nanoparticle 110, the band gap E_{NP} of the Group IV semiconductor nanoparticle 110, must be matched to the band gap E_{B} of the bulk 115 in order for the charges to be transferred in the bulk 115, before charge collection takes place in doped layers, as will be discussed in more detail subsequently.

Regarding the terminology of the art for Group IV semiconductor thin film materials, the term “amorphous” is generally defined as noncrystalline material lacking long-range periodic ordering, while the term “polycrystalline” is generally defined as a material composed of crystallite grains of different crystallographic orientation, where the amorphous state is either absent or minimized (e.g. within the grain boundary and having an atomic monolayer in thickness). With respect to the term “microcrystalline”, in some current definitions, this represents a thin film having properties between that of amorphous and polycrystalline, where the crystal volume fraction may range between a few percent to about 90%. In that regard, on the upper end of such a definition, there is arguably a continuum between that which is microcrystalline and polycrystalline. For the purpose of what is described herein, “microcrystalline” is a thin film in which microcrystallites are embedded in an amorphous matrix, and “polycrystalline” is not constrained by crystallite size, but rather a thin film having properties reflective of the highly crystalline nature.

The Group IV semiconductor nanoparticles may be made according to any suitable method, several of which are known, provided they are initially formed in an environment that is substantially inert, and substantially oxygen-free. As used herein, “inert” is not limited to only substantially oxygen-free. It is recognized that other fluids (i.e. gases, solvents, and solutions) may react in such a way that they negatively affect the electrical and photoconductive properties of Group IV semiconductor nanoparticles. Additionally, the terms “substantially oxygen-free” in reference to environments, solvents, or solutions refer to environments, solvents, or solutions wherein the oxygen content has been substantially reduced to produce Group IV semiconductor thin films having no more than 10¹⁷ to 10¹⁹ oxygen per cubic centimeter of Group IV semiconductor thin film. For example, it is contemplated that plasma phase preparation of hydrogen-terminated Group IV semiconductor nanoparticles is done in an inert, substantially oxygen-free environment. As such, plasma phase methods produce nanoparticle materials of the quality suitable for making embodiments of Group IV semiconductor thin film devices. For example, one plasma phase method, in which the particles are formed in an inert, substantially oxygen-free environment, is disclosed in U.S. patent application Ser. No. 11/155,340, filed Jun. 17, 2005; the entirety of which is incorporated herein by reference.

It is contemplated that embodiments of doped Group IV semiconductor nanoparticles can be utilized to fabricate doped Group IV semiconductor thin film devices. In that regard, during plasma phase preparation, dopants can be introduced in to gas phase during the formation and growth of Group IV semiconductor nanoparticles. For example, n-type Group IV semiconductor nanoparticles may be prepared using a plasma phase method in the presence of well-known gases such as phosphorous oxychloride, phosphine, or arsine. Alternatively, p-type semiconductor nanoparticles may be prepared in the presence of boron diflouride, trimethyl borane, or diborane. For core/shell Group IV semiconductor nanoparticles, the dopant may be in the core or the shell or both the core and the shell.

After the preparation of quality Group IV semiconductor nanoparticles in an inert, substantially oxygen-free environment, the particles are formulated as dispersions or inks in an inert, substantially oxygen-free environment, so that they can be deposited on a solid support. In terms of preparation of the dispersions, the use of particle dispersal methods such as sonication, high shear mixers, and high pressure/high shear homogenizers are contemplated for use to facilitate dispersion of the particles in a selected solvent or mixture of solvents. For example, inert dispersion solvents contemplated for use include, but are not limited to chloroform, tetrachloroethane, chlorobenzene, xylenes, mesitylene, diethylbenzene, 1,3,5 triethylbenzene (1,3,5 TEB), and combinations thereof.

Various embodiments of Group IV semiconductor nanoparticle inks can be formulated by the selective blending of different types of Group IV semiconductor nanoparticles. For example, varying the packing density of Group IV semiconductor nanoparticles in a deposited thin layer is desirable for forming a variety of embodiments of Group IV photoconductive thin films. In that regard, Group IV semiconductor nanoparticle inks can be prepared in which various sizes of monodispersed Group IV semiconductor nanoparticles are specifically blended to a controlled level of polydispersity for a targeted nanoparticle packing. Further, Group IV semiconductor nanoparticle inks can be prepared in which various sizes, as well as shapes are blended in a controlled fashion to control the packing density.

Still another example of what may achieved through the selective formulation of Group IV semiconductor nanoparticle inks by blending doped and undoped Group IV semiconductor nanoparticles. For example, various embodiments of Group IV semiconductor nanoparticle inks can be prepared in which the dopant level for a specific thin layer of a targeted device design is formulated by blending doped and undoped Group IV semiconductor nanoparticles to achieve the requirements for that layer. In still another example are embodiments of Group IV semiconductor nanoparticle inks that may compensate for defects in embodiments of Group IV photoconductive thin films. For example, it is known that in an intrinsic silicon thin film, low levels of oxygen may act to create undesirable trap states. To compensate for this, low levels of p-type dopants, such as boron diflouride, trimethyl borane, or diborane, may be used to compensate for the presence of low levels of oxygen. By using Group IV semiconductor nanoparticles to formulate embodiments of inks, such low levels of p-type dopants may be readily introduced in embodiments of blends of the appropriate amount of p-doped Group IV semiconductor nanoparticles with various types of undoped Group IV semiconductor nanoparticles.

Other embodiments of Group IV semiconductor nanoparticle inks can be formulated that adjust the band gap of embodiments of Group IV photoconductive thin films. For example, the band gap of silicon is about 1.1 eV, while the band gap of germanium is about 0.7 eV, and for alpha-tin is about 0.05 eV. Therefore, formulations of Group IV semiconductor nanoparticle inks may be selectively formulated so that embodiments of Group IV photoconductive thin films may have photon adsorption across a wider range of the electromagnetic spectrum.

Finally, embodiments of Group IV semiconductor nanoparticle inks may be prepared that have a targeted fabrication temperature for a deposited nanoparticle thin film in the formation of photoconductive thin films by exploiting nanoparticle size, elemental composition, and combinations thereof. For example, as will be discussed in more detail subsequently, the fabrication temperatures for the various layers in a multi-layer device must be carefully considered, so as to avoid undesirable effects, for example such as dopant redistribution, and the potential for forming defects at a reforming interface. In this regard, given that there is a direct correlation between nanoparticle size and melting temperature for silicon nanoparticles between the size range of about 1 nm to about 15 nm, then nanoparticles of a specific size or size range may be formulated for a desired fabrication temperature. Further, germanium nanoparticles of comparable size to silicon nanoparticles melt at a lower temperature, so where types of nanoparticle materials having more than one type of Group IV semiconductor element are indicated, the melting temperatures of the materials may be exploited.

The thin film of deposited Group IV semiconductor nanoparticles is then fabricated into a Group IV semiconductor thin film. The fabrication steps are done in an inert, substantially oxygen free environment, using temperatures between about 300° C. to about 900° C. Heat sources contemplated for use include conventional contact thermal sources, such as resistive heaters, as well as radiative heat sources, such as lasers, and microwave processing equipment. More specifically, lasers operating in the wavelength range between 0.5 micron to 10 micron, and microwave processing equipment operating in even longer wavelength ranges are matched to the fabrication requirements of embodiments of Group IV semiconductor thin films described herein. These types of apparatuses have the wavelengths for the effective penetration the film thicknesses, as well as the power requirements for fabrication of such thin film devices.

Regarding the time required to fabricate a deposited Group IV nanoparticle thin film into a Group IV photoconductive thin film, the time required varies as an inverse function in relation to the fabrication temperature. For example, if the fabrication temperature is about 800° C., then for various embodiments of Group IV photoconductive thin films, the fabrication time may be, for example, between about 5 minutes to about 15 minutes. However, if the fabrication temperature is about 400° C., then for various embodiments of Group IV photoconductive thin films, the fabrication temperature may be between about, for example, 1 hour to about 10 hours. The fabrication process may also optionally include the use of pressure of up about 7000 psig. The process of preparing Group IV semiconductor thin films from Group IV semiconductor nanoparticle materials has been described in US Provisional Application [App. Ser. No. 60/842,818], with a filing date of Sep. 7, 2006, and entitled, “Semiconductor Thin Films Formed from Group IV Nanoparticles.” The entirety of this application is incorporated by reference.

Other considerations for greatly reducing or eliminating defects during the fabrication of Group IV semiconductor nanoparticle thin films to form photoconductive Group IV semiconductor thin films include: 1.) controlling the fabrication parameters of temperature and pressure, 2.) optimizing the film thicknesses, 3.) sequential deposition and fabrication of strata of a layer to decrease defects in a layer, and 4.) the selection of the type of Group IV nanoparticle material for a targeted photoconductive Group IV semiconductor thin film.

Controlling the fabrication parameters of temperature and pressure, and optimizing film thickness ensure that structural defects will be minimized or eliminated during fabrication in order to maximize the yield of functional devices. Generally, it is desirable to select the minimal fabrication temperature and time for achieving the conversion of the Group IV semiconductor nanoparticle thin films to Group IV photoconductive thin films. This not only has an impact on process costs, but moreover acts to minimize the redistribution of dopant molecules during photoconductive thin film fabrication from deposited nanoparticle thin films, and may reduce stress defects, as well. In that regard, the use of a ramp rate of the temperature and optionally the pressure conditions may also ensure that the Group IV semiconductor nanoparticle thin films experience no initial untoward thermal or baric stress. Additionally, the appropriate ramp rates of the fabrication parameters ensure evenness of fabrication conditions throughout the processing apparatus, and hence throughout the multiple layers of devices being made, also decreasing the probability of inducing stress such multiple layers during fabrication thereby.

Film thickness is optimized to target Group IV nanoparticle film thicknesses that will result in Group IV photoconductive thin films of sufficient thickness to provide the targeted function, but as thin as possible to achieve that result in order to minimize the formation of structural defects during fabrication. In terms of minimizing such defects, a stepwise process may be used to deposit sequential strata of the same type of Group IV semiconductor nanoparticle ink in order to fabricate a single thin film layer. Such a method may be effective in repairing mechanical defects, such as pin holes or cracks, formed in a first fabricated stratum by the subsequent deposition of a second stratum of a Group IV semiconductor nanoparticle ink, followed by the stepwise fabrication of the strata. There is a low probability of defects aligning during such a stepwise fabrication of a single layer, thereby serving as a useful process for increasing yield. The ease of application of Group IV nanoparticle inks, providing deposition of a range of thicknesses of Group IV nanoparticle thin films, provides for ready integration of either sequential or stepwise methods into Group IV photoconductive thin film fabrication.

Finally, embodiments of nanoparticle thin films having specific functionality may be derived from variations of the nanoparticle material crystallinity, elemental composition, size, and shape. More specifically, various embodiments of Group IV semiconductor thin film devices can be fabricated by varying the particle sizes and shapes to adjust the packing density of the deposited Group IV semiconductor nanoparticle thin film, as well as varying the nanoparticle elemental composition and size to adjust the fabrication temperature of such deposited thin films, as previously discussed.

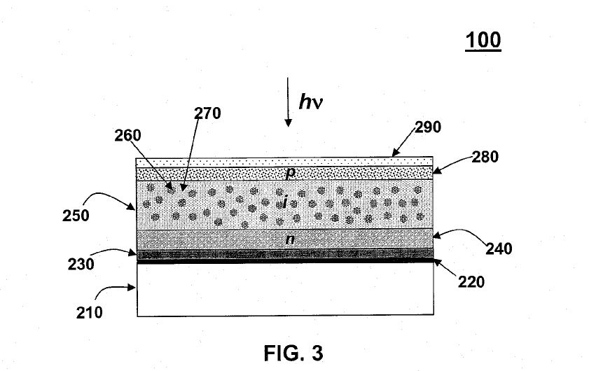

An example of an embodiment of a Group IV photoconductive device having enhanced efficiency is shown in FIG. 3. A single junction p/i/n device 100 of FIG. 3 is shown starting with substrate 210, upon which a first electrode, 230, and optionally an insulating layer 220 between the substrate 210 and electrode 230 are deposited. For some embodiments of single junction p/i/n device 100, substrate materials may be selected from silicon dioxide-based substrates. Such silicon dioxide-based substrates include, but are not limited by, quartz, and glasses, such as soda lime and borosilicate glasses. For other embodiments of Group IV semiconductor single junction p/n device 100, flexible stainless steel sheet is the substrate of choice, while for still other embodiments of single junction p/i/n device 100, the substrate may be selected from heat-durable polymers, such as polyimides and aromatic fluorene-containing polyarylates, which are examples of polymers having glass transition temperatures above about 300° C.

The first electrode 230 is selected from conductive materials, such as, for example, aluminum, molybdenum, chromium, titanium, nickel, and platinum. For various embodiments of photoconductive devices contemplated, the first electrode 230 is between about 10 nm to about 1000 nm in thickness. Optionally, an insulating layer 220 may be deposited on the substrate 210 before the first electrode 230 is deposited. Such an optional layer is useful when the substrate is a dielectric substrate, since it protects the subsequently fabricated Group IV semiconductor thin films from contaminants that may diffuse from the substrate into the Group IV semiconductor thin film during fabrication. When using a conductive substrate, the insulating layer 220 not only protects Group IV semiconductor thin films from contaminants that may diffuse from the substrate, but is required to prevent shorting. Additionally, an insulating layer 220 may be used to planarize an uneven surface of a substrate. The insulating layer 220 is selected from dielectric materials such as, for example, but not limited by, silicon nitride and alumina. For various embodiments of photoconductive devices contemplated the insulating layer 220 is about 5 nm to about 100 nm in thickness.

Regarding the active layers in FIG. 3, upon first electrode layer 230, a first n-doped Group IV semiconductor thin layer 240 is shown, upon which an intrinsic Group IV semiconductor thin layer 250 is shown. Group IV semiconductor thin layer 250 is a composition of a Group IV semiconductor nanoparticles 260 embedded in a Group IV semiconductor matrix material 270. On Group IV semiconductor thin layer 250, a Group IV semiconductor p-doped thin layer 280 is shown. Finally, a transparent conductive oxide (TCO) layer 290 is deposited on the p-doped layer to complete the fabrication of a p/i/n Group IV semiconductor photoconductive device. Materials useful for the TCO layer 290 include, but are not limited by indium tin oxide (ITO), tin oxide (TO), and zinc oxide (ZnO). As one of ordinary skill in the art is apprised, for many embodiments of device 100 of FIG. 3, the intrinsic layer 250, which functions as a photon absorbing layer, is thicker than the n-doped layer 240 and the p-doped layer 280. For example, intrinsic layer 250 may be between about 0.2 microns to about 3 microns, while n-doped layer 240 and p-doped layer 280 may be between about 10 nm to about 100 nm in thickness. The TCO layer 290 is between about 100 nm to about 200 nm in thickness.

To maintain the Group IV semiconductor nanoparticles 260 in an intact state in order to preserve the desired quantum confinement effects for the MEG efficiency enhancement, ink formulations exploiting particle size and for targeting fabrication temperatures of active layers 240, 250, and 280 are contemplated.

For example, for embodiments of devices such as those of FIG. 3, for the fabrication of the first n-doped layer 240, a Group IV semiconductor nanoparticle layer is deposited using an embodiment of a Group IV semiconductor n-doped nanoparticle ink formulated from amorphous or crystalline silicon nanoparticles, and combinations thereof in the size range of about between 1 nm to about 4 nm in diameter. Alternatively, thin film 240 is formed using a nanoparticle ink formulated from amorphous or crystalline silicon nanoparticles, and combinations thereof in the size range of about between 2 nm to about 4 nm in diameter, and subsequently n-doped using, for example, standard procedures for thin film doping with phosphine, arsine, or phosphorous oxychloride. In this example, silicon nanoparticles of this diameter will have a fabrication temperature T₁.

As previously mentioned, in order to preserve the quantum confined nanoparticles 260 in their nanoparticle state, the matrix material 270 of the intrinsic layer 250 will have a fabrication temperature that will be less than the fabrication temperature of the larger, quantum confined nanoparticles 260. In that regard, in the embodiments of ink formulations for the intrinsic layer 250, silicon nanoparticles for the embedded nanoparticle material 260 may be between, for example, about 5 nm to about 15 nm in diameter, and would have a fabrication temperature of T₂, while the silicon nanoparticles for the matrix material 270 may be selected from undoped amorphous and crystalline silicon nanoparticles, and combinations thereof in the size range of between about, for example, 1 nm to about 4 nm in diameter, having a lower fabrication temperature T₁. Intrinsic photoconductive layer 250, may also be formed using a silicon nanoparticle ink specifically formulated using a blend of silicon nanoparticles, and an appropriate amount of a p-doped silicon nanoparticles both in the size range of between about, for example, 1 nm to about 4 mm in diameter, so as to compensate for contaminants, such as oxygen, which may then act to create undesirable trap states. The embedded Group IV semiconductor nanoparticles 260 may be formulated in embodiments of inks used for the deposition a Group IV semiconductor nanoparticle intrinsic layer as a first step in the fabrication of intrinsic layer 250 to be between about 10% to about 50% of the total particle population in the ink formulations. The considerations for the range of between about 10% to about 50% of the quantum confined nanoparticles 260 in the total population of nanoparticles used embodiments of ink formulations used for fabricating intrinsic layer 250 include that there should be enough of the quantum confined particles 260 in the intrinsic layer 250 for there to be a pronounced effect, but not so many centers that there would be an insufficient quantity of matrix material 270 for collection of the electrons and holes, as shown in FIG. 2.

Finally, regarding the fabrication of p-doped photoconductive layer 280 for embodiments of devices such as those of FIG. 3, a Group IV semiconductor nanoparticle thin film layer is first deposited using an embodiment of a Group IV semiconductor p-doped nanoparticle ink formulated from amorphous or crystalline silicon nanoparticles, and combinations thereof in the size range of about between 2 nm to about 4 nm in diameter. Alternatively, thin film 280 fabricated by using a nanoparticle ink formulated from amorphous or crystalline silicon nanoparticles, and combinations thereof in the size range of about between 2 nm to about 4 nm in diameter to deposit a Group IV semiconductor nanoparticle thin film, and subsequently p-doped using, for example, standard procedures for thin film doping with boron diflouride, trimethyl borane, or diborane. As for the examples of the n-doped layer 240, and matrix material 270 of intrinsic layer 250, then p-doped layer 280 also has a fabrication temperature T₁.

As given in this example, the particle diameter of the type of Group IV nanoparticle material selected for the n-doped photoconductive layer 240, matrix material 270, and p-doped photoconductive layer 280 is smaller than the diameter of Group IV nanoparticle material selected for the embedded nanoparticles 260. In that regard, nanoparticle layers could be sequentially deposited on electrode layer 230 using exemplary inks as described in the above for the n-doped layer deposited nanoparticles, intrinsic layer deposited nanoparticles, and p-doped layer deposited nanoparticles, and then fabricated at temperature T₁ to produce photoactive layers 240, 250, and 280.

As will be evident to one of ordinary skill in the art, additional embodiments of methods for preparing multi-layer photoconductive devices, such as that shown in FIG. 3 are possible by applying the approach of preparing Group IV semiconductor inks by blending different types of Group IV semiconductor nanoparticle materials, which materials have targeted nanoparticle sizes and elemental compositions, so that the various layers in a multilayer device have targeted fabrication temperatures.

For example, for the fabrication of n-doped layer 240, a Group IV semiconductor nanoparticle thin film may be first deposited using an embodiment of a Group IV semiconductor n-doped nanoparticle ink formulated from amorphous or crystalline silicon nanoparticles, and combinations thereof in the size range of between about 5 nm to about 15 nm in diameter, and has a higher fabrication temperature than subsequently deposited intrinsic layer 250. As given in the previous example, in embodiments of ink formulations for the intrinsic layer 250, silicon nanoparticles for the embedded nanoparticle material 260 may be between about, for example, 5 nm and 15 nm in diameter, and would have a fabrication temperature of equivalent to the first fabricated n-doped layer 240, while the silicon nanoparticles for the matrix material 270 may be selected from undoped amorphous and crystalline silicon nanoparticles, and combinations thereof in the size range of between about, for example, 1 nm to about 4 nm in diameter, having a lower fabrication temperature. Accordingly, in order to avoid dopant redistribution, and the potential for forming defects at a reforming interface, the subsequently deposited intrinsic nanoparticle layer would be fabricated at a lower temperature than the first fabricated n-doped photoconductive layer 240.

Further variations of methods for fabricating embodiments of device 100 of FIG. 3 are drawn in contemplating the fabrication of p-doped layer 280. In one embodiment of a method for fabrication, after the fabrication of n-doped layer 240 at a higher temperature, the Group IV semiconductor nanoparticle layers for both the intrinsic layer 250 and the p-doped layer could be sequentially deposited from embodiments of inks using silicon nanoparticles in the size range of between about, for example, 1 nm to about 4 nm in diameter, and then fabricated at a lower temperature than that of photoconductive n-doped layer 240 to form intrinsic photoconductive layer 250 and p-doped photoactive layer 280. In still another embodiment of a method for fabricating device 100, silicon nanoparticles for the embedded nanoparticle material 260 may be between about, for example, 5 nm and 15 nm in diameter, and would have a fabrication temperature of equivalent to the first fabricated n-doped layer 240, while the silicon nanoparticles for the matrix material 270 may be selected from undoped amorphous and crystalline silicon nanoparticles, and combinations thereof in the size range of between about, for example, 1 nm to about 4 nm in diameter, and would be fabricated at the lower temperature to form photoconductive intrinsic layer 250, with quantum confined silicon nanoparticles 260. Either before or subsequently to fabrication, a defined layer of photoconductive intrinsic layer 250 could be p-doped using standard procedures for thin film doping with boron diflouride, trimethyl borane, or diborane. Additional methods of fabricating embodiments of device 100 may exploit the elemental composition of Group IV semiconductor nanoparticles. For example, germanium nanoparticles of comparable size to silicon nanoparticles melt at a lower temperature, so where types of nanoparticle materials having more than one type of Group IV semiconductor element are indicated, the melting temperatures of the materials may be exploited in formulations of inks for targeting the fabrication temperature of a specific layer in a multilayered device.

Regarding the embedded Group IV nanoparticles 260, varieties of embodiments of device 100 of FIG. 3 may arise from the selection of the type of Group IV semiconductor nanoparticle, or blend thereof, which is used to formulate the Group IV nanoparticle ink used for the deposition of embodiments of a Group IV semiconductor nanoparticle thin film, which nanoparticle thin film is subsequently fabricated to form intrinsic layer 250. Consideration is given for the size range for each elemental composition of Group IV semiconductor nanoparticle in which the quantum confinement effect is manifest. For example, for the silicon nanoparticles, the range of nanoparticle dimensions for quantum confined behavior is between about 1 nm to about 15 nm, while for germanium nanoparticles, the range of nanoparticle dimensions for quantum confined behavior is between about 1 nm to about 35 nm, and for alpha-tin nanoparticles, the range of nanoparticle dimensions for quantum confined behavior is between about 1 nm to about 40 nm.

Additionally, alloys of the Group IV semiconductor nanoparticles are contemplated for the embedded Group IV nanoparticles 260, varieties of embodiments of device 100 of FIG. 3. For example, nanoparticle materials which are alloys of silicon and germanium may vary depending on the ratio of silicon and germanium in the alloy. In that regard, some embodiments of silicon/alpha tin alloy nanoparticle materials have a range of nanoparticle dimensions for quantum confined behavior closer to silicon, or between is between about 1 nm to between about 20 nm, while other embodiments of silicon/alpha tin alloy nanoparticle materials have a range of nanoparticle dimensions for quantum confined behavior closer to silicon, or between is between about 1 nm to about 30 nm.

Consideration of the selection of type of Group IV nanoparticle material, or blend of materials for the quantum confined Group IV nanoparticles 260 in intrinsic layer 250 of device 100 in FIG. 3 include the impact of the material on the MEG effect, as well as the selection of the appropriate size range for targeted fabrication method, and associated targeted fabrication temperature for device 100. As previously stated, the band gap of silicon is about 1.1 eV, while the band gap of germanium is about 0.7 eV, and for alpha-tin is about 0.05 eV. In that regard, the embodiments of device 100 arise from the selection of the type of Group IV nanoparticle material or blends thereof formulated in embodiments of inks used for the deposition of embodiments of a Group IV semiconductor nanoparticle thin film, which nanoparticle thin film is subsequently fabricated to form intrinsic layer 250. Such which can harvest energetic photons, creating multiple exciton generation (MEG) thereby. Additional embodiments of ink formulations for the intrinsic layer 250 may thereby arise from the use of a variety of Group IV semiconductor nanoparticles for embedded, quantum confined nanoparticles 260.

For example, inks are contemplated in which germanium nanoparticles of between about, for example, 15 nm and about 35 nm in diameter are selected for the embedded nanoparticle material 260 and would have a fabrication temperature of T₁, while the silicon nanoparticles for the matrix material 270 may be selected from undoped amorphous and crystalline silicon nanoparticles, and combinations thereof in the size range of between about, for example, 1 nm to about 4 nm in diameter, having a lower fabrication temperature T₂. In still another example, a mixture of silicon nanoparticles of between about, for example, 5 nm and 15 nm in diameter, and having a fabrication temperature T₁ and germanium nanoparticles of between, for example, about 15 nm to about 20 nm in diameter, and having a fabrication temperature of T₂ are selected for the embedded nanoparticle material 260, while the silicon nanoparticles for the matrix material 270 may be selected from undoped amorphous and crystalline silicon nanoparticles, and combinations thereof in the size range of between about, for example, 1 nm to about 4 nm in diameter, having a lower fabrication temperature T₃ than either the fabrication temperatures for T₁ and T₂. In both examples given, embodiments of semiconductor nanoparticles 260 may be formulated in embodiments of inks used for the deposition of embodiments of a Group IV intrinsic nanoparticle thin film layer to be between about 10% to about 50% of the total particle population in the ink formulations. As will be apparent to one of ordinary skill in the art, Group IV nanoparticles selected from silicon, germanium, alpha-tin, alloys, core/shell particles, and combinations thereof can be selected for use as embedded nanoparticle material 260 in intrinsic layer 250 of device 100.

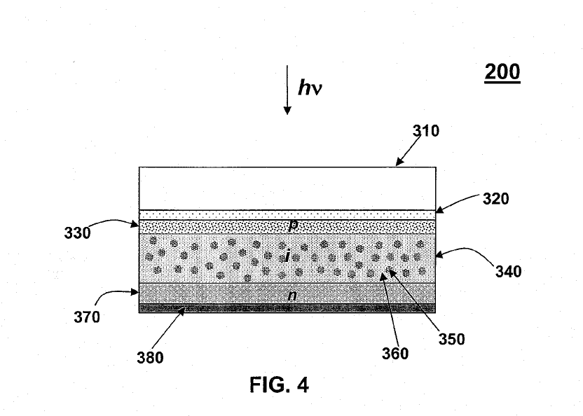

In FIG. 4, another embodiment of a photoconductive device 200 is shown, and may readily be fabricated using methods as described for device 100 of FIG. 3. Regarding the active layers, the thickness of the photoconductive intrinsic thin film layer 340 is between about 0.2 microns to about 3.0 microns in thickness, while the p-doped and n-doped photoconductive layers 330 and 370 are between about 10 nm to about 100 nm in thickness. The second electrode 380 is selected from conductive materials, such as, for example, aluminum, molybdenum, chromium, titanium, nickel, and platinum, and is between about 10 nm to about 1000 nm in thickness for the various embodiments of a Group IV photoconductive, such as that shown in FIG. 4. Upon substrate 310, a TCO layer 320 of between about 100 nm to about 200 nm would be deposited. The nanoparticle ink used for the deposition of embodiments of Group IV semiconductor nanoparticle thin film layers, which nanoparticle thin film layers are fabricated to form doped layers 330 and 370 of p/i/n device 300, could be formulated using doped amorphous silicon nanoparticles, doped crystalline germanium nanoparticles, or combinations thereof. Alternatively, the thin film formed from amorphous silicon nanoparticles, doped crystalline germanium nanoparticles, or combinations thereof is then subsequently doped using standard procedures, as previously discussed.

The nanoparticle ink used for the deposition Group IV semiconductor nanoparticle thin film layers, which nanoparticle thin film layers are fabricated to form the matrix material 360 of intrinsic layer 340 of p/i/n device 300, could be formulated using amorphous silicon and crystalline germanium nanoparticles, or also be formed using a nanoparticle ink specifically formulated using a blend of Group IV nanoparticles, and an appropriate amount of a p-doped Group IV nanoparticles, so as to compensate for contaminants, such as oxygen, which may then act to create undesirable trap states. Regarding the selection of embedded, quantum confined Group IV nanoparticles 350, embodiments of intrinsic layer 340 arise from the selection of nanoparticles possible, as previously discussed, in accordance with the previous discussions related to choice of material for formulation of inks for targeted fabrication methods and processes thereof.

Moreover, it is contemplated that combinations of different types of fabrication methods can be integrated to create embodiments of Group IV photoconductive the devices shown in FIG. 3. and FIG. 4. For example, plasma enhanced chemical vapor deposition (PECVD) can currently deposit crystalline hydrogen terminated silicon thin films at the rate of between about 0.1 to about 5 Å/s. While the quality of the crystalline material is high, the process suffers from a low film deposition rate, increasing the cost of photoconductive thin films fabricated thereby. In that regard, given the upper end of the intrinsic layer film thickness of 3 microns, even at the highest rate of deposition, this would require about 2 hours of PECVD processing to deposit such a layer. In contrast, the deposition of a 3 micron layer of nanoparticles, followed by fabrication to produce a Group IV photoconductive thin film layer is significantly faster, and may be about only 10% of the time. Accordingly, the combination of the PECVD process and processes disclosed herein may be used to fabricate embodiments of Group IV photoconductive the devices of FIG. 3 and FIG. 4.

For example, for embodiments of device 100 of FIG. 3 and embodiments of device 200 of FIG. 4, as previously mentioned, the p-doped and n-doped layers of these devices are for charge collection, while the intrinsic layers 250 of device 100 in FIG. 3, and 340 of device 200 in FIG. 4 are for photon absorption, as well as acting in the transfer of charges formed in the quantum confined nanostructures 260 and 350. In that regard, embodiments of intrinsic layers 250 and 340 may be fabricated as described previously. However, for embodiments of n-doped layers 240 of device 100 in FIG. 3, and 370 of device 200 in FIG. 4, as well as for embodiments of p-doped layers 280 of device 100 in FIG. 3, and 330 of device 200 in FIG. 4, these layers could be fabricated using a PECVD process.

From what has been previously discussed, the utility realized in fabricating native Group IV photoconductive thin films from embodiments of Group IV semiconductor nanoparticle ink formulations includes, but is not limited by: 1.) Control over formulating inks that selectively blend the appropriate particle sizes and shapes to achieve a targeted nanoparticle pack density in a deposited thin film; 2.) Control over formulating inks that have the appropriate amount of doped nanoparticle to undoped nanoparticle in order to achieve the desired performance for a specific doped layer in a targeted device embodiment; 3.) Control over formulating inks that are appropriately adjusted with dopant levels to compensate for contaminants in order to achieve the desired performance for a specific intrinsic layer in a targeted device embodiment; 4.) Control over formulating Group IV semiconductor nanoparticle inks for adjusting the photon adsorption over a wider range of the electromagnetic spectrum; 5.) Control over formulating Group IV semiconductor nanoparticle inks for adjusting the capture of energetic photon adsorption, creating multiple exciton generation, and enhancing efficiency thereby; and 6.) Capability to rapidly deposit multiple layers over a range of thicknesses, resulting in reduced fabrication time, as well as increase in yield through defect control.

While principles of the disclosed enhanced efficiency photoconductive Group IV semiconductor thin film devices and methods for making such devices have been described in connection with specific embodiments, it should be understood clearly that these descriptions are made only by way of example and are not intended to limit the scope of what is disclosed. In that regard, what has been disclosed herein has been provided for the purposes of illustration and description. It is not intended to be exhaustive or to limit what is disclosed to the precise forms described. Many modifications and variations will be apparent to the practitioner skilled in the art. What is disclosed was chosen and described in order to best explain the principles and practical application of the disclosed embodiments of the art described, thereby enabling others skilled in the art to understand the various embodiments and various modifications that are suited to the particular use contemplated. It is intended that the scope of what is disclosed be defined by the following claims and their equivalence.

1-20. (canceled)

21. A device for generating a plurality of electron-hole pairs from a photon, comprising:
a substrate;
a first electrode formed above the substrate;
a first doped Group IV nanoparticle thin film deposited on the first electrode;
an intrinsic layer deposited on the first doped Group IV nanoparticle thin film, wherein the intrinsic layer includes a matrix material with a melting temperature T1, wherein T1 is greater than about 300° C., and a set of quantum confined nanoparticles each with a melting temperature T2, wherein T2 is less than about 900° C., wherein the melting temperature T1 is less than the melting temperature T2;
a second doped Group IV nanoparticle thin film deposited on the intrinsic layer; and,
a second electrode formed on the second doped Group IV nanoparticle thin film;
wherein when the photon is absorbed by a quantum confined nanoparticle of the set of quantum confined nanoparticles, the plurality of electron-hole pairs is generated.

22. The device of claim 21, wherein the set of quantum confined nanoparticles is a between about 10% to about 50% of the intrinsic layer.

23. The device of claim 21, wherein the set of quantum confined nanoparticles includes at least one of silicon, germanium, and alpha-tin.

24. The device of claim 21, wherein the substrate includes an insulating layer.

25. The device of claim 21, wherein the matrix material includes Group IV microcrystalline nanoparticles.

26. The device of claim 21, wherein the matrix material includes Group IV amorphous nanoparticles.

27. The device of claim 21, wherein the first doped Group IV nanoparticle thin film is n-doped, while the second doped Group IV nanoparticle thin film is p-doped.

28. The device of claim 21, wherein the first doped Group IV nanoparticle thin film is p-doped, while the second doped Group IV nanoparticle thin film is n-doped.

29. The device of claim 21, wherein the matrix material includes Group IV amorphous nanoparticles.

30. The device of claim 21, wherein the intrinsic layer has a thickness of between about 0.2 microns and 3.0 microns.

31. The device of claim 21, wherein the first doped Group IV nanoparticle thin film has a thickness of between about 10 nm and about 100 nm.

32. The device of claim 21, wherein the second doped Group IV nanoparticle thin film has a thickness of between about 10 nm and about 100 nm.

33. The device of claim 21, wherein the second electrode is TCO.

34. The device of claim 21, wherein the first electrode includes at least one of aluminum, molybdenum, chromium, titanium, nickel, and platinum.

35. A method of manufacturing a device for generating a plurality of electron-hole pairs from a photon, comprising:
providing a substrate;
forming a first electrode above the substrate;
forming a first doped Group IV nanoparticle thin film on the first electrode;
depositing an intrinsic ink including,
a matrix material including silicon nanoparticles with a first size range of between about 1 nm and about 4 nm and a melting temperature T1, wherein T1 is greater than about 300° C., and
a set of quantum confined silicon nanoparticles with a second size range greater than about 4 mm and a melting temperature T2, wherein T2 is less than about 900° C., wherein the melting temperature T1 is less than the melting temperature T2;
heating the intrinsic ink to a temperature of about T1, wherein an intrinsic thin film is formed;
forming a second doped Group IV nanoparticle thin film on the intrinsic thin film;
forming a second electrode on the second doped Group IV nanoparticle thin film.

36. The method of claim 35, wherein the set of quantum confined silicon nanoparticles is a between about 10% to about 50% of the intrinsic thin film.

37. The method of claim 35, wherein the first doped Group IV nanoparticle thin film is n-doped, while the second doped Group IV nanoparticle thin film is p-doped.

38. The method of claim 35, wherein the first doped Group IV nanoparticle thin film is p-doped, while the second doped Group IV nanoparticle thin film is n-doped.

39. A method of manufacturing a device for generating a plurality of electron-hole pairs from a photon, comprising:
providing a substrate;
forming a first electrode above the substrate;
forming a first doped Group IV nanoparticle thin film on the first electrode;
depositing an intrinsic ink including,
a matrix material including silicon nanoparticles with first melting temperature greater than about 300° C., and
a set of quantum confined germanium nanoparticles with second temperature less than about 900° C., wherein the first melting temperature is less than the second temperature T2;
heating the intrinsic ink to a temperature of about the first melting temperature, wherein an intrinsic thin film is formed;
forming a second doped Group IV nanoparticle thin film on the intrinsic thin film;
forming a second electrode on the second doped Group IV nanoparticle thin film.

40. The method of claim 39, wherein the set of quantum confined germanium nanoparticles is a between about 10% to about 50% of the intrinsic thin film.

41. The method of claim 39, wherein the first doped Group IV nanoparticle thin film is n-doped, while the second doped Group IV nanoparticle thin film is p-doped.

42. The method of claim 39, wherein the first doped Group IV nanoparticle thin film is p-doped, while the second doped Group IV nanoparticle thin film is n-doped.

43. A method of manufacturing a device for generating a plurality of electron-hole pairs from a photon, comprising:
providing a substrate;
forming a first electrode above the substrate;
forming a first doped Group IV nanoparticle thin film on the first electrode;
depositing an intrinsic ink including,
a matrix material including silicon nanoparticles with first melting temperature greater than about 300° C., and
a set of quantum confined alpha-tin nanoparticles with a second melting temperature less than about 900° C., wherein the first melting temperature is less than the second melting temperature;
heating the intrinsic ink to a temperature of about the first melting temperature, wherein an intrinsic thin film is formed;
forming a second doped Group IV nanoparticle thin film on the intrinsic thin film;
forming a second electrode on the second doped Group IV nanoparticle thin film.

44. The method of claim 43, wherein the set of quantum confined alpha-tin nanoparticles is a between about 10% to about 50% of the intrinsic thin film.

45. The method of claim 43, wherein the first doped Group IV nanoparticle thin film is n-doped, while the second doped Group IV nanoparticle thin film is p-doped.

46. The method of claim 43, wherein the first doped Group IV nanoparticle thin film is p-doped, while the second doped Group IV nanoparticle thin film is n-doped.
